(19) United States
(12) Patent Application Publication
(10) Pub. No.: US 2026/0312552 A1
(43) Pub. Date: Oct. 8, 2026

(54) POWER AMPLIFIER CIRCUIT AND POWER AMPLIFIER DEVICE

(71) Applicant: Murata Manufacturing Co., Ltd., Nagaokakyo-shi (JP)

(72) Inventors: Ryo TAMURA, Nagaokakyo-shi (JP); Yuri Honda, Nagaokakyo-shi (JP); Kenji Mukai, Nagaokakyo-shi (JP); Hiroshi Okabe, Nagaokakyo-shi (JP)

(21) Appl. No.: 19/682,728

(22) Filed: May 20, 2026

Related U.S. Application Data
(63) Continuation of application No. PCT/JP2024/038604, filed on Oct. 30, 2024.

(30) Foreign Application Priority Data
Jan. 5, 2024 (JP) 2024-000742

(51) Int. Cl. H03F 3/45

(52) U.S. Cl. CPC H03F 3/45076

(57) ABSTRACT

A power amplifier circuit includes a first carrier amplifier, a first peak amplifier, a second carrier amplifier, a second peak amplifier, a first capacitor, a second capacitor, first wiring, second wiring, a balun, and third wiring. The first carrier amplifier amplifies a first split signal obtained by splitting a first signal which is one of a pair of balanced signals, and outputs a first amplified signal from a first output terminal. The first peak amplifier amplifies a second split signal which is obtained by splitting the first signal and which is different in phase from the first split signal, and outputs a second amplified signal from a second output terminal. The second carrier amplifier amplifies a third split signal obtained by splitting a second signal which is the other of the pair of balanced signals, and outputs a third amplified signal from a third output terminal.

### CROSS REFERENCE TO RELATED APPLICATION

This is a continuation of International Application No. PCT/JP2024/038604 filed on Oct. 30, 2024 which claims priority from Japanese Patent Application No. 2024-000742 filed on Jan. 5, 2024. The contents of these applications are incorporated herein by reference in their entireties.

### BACKGROUND OF THE DISCLOSURE

### Field of the Disclosure

The present disclosure relates to a power amplifier circuit and a power amplifier device.

### Description of the Related Art

There is a power amplifier circuit in which a Doherty amplifier has a differential configuration and in which a transformer for impedance conversion is connected to the differential output end (for example, see Japanese Unexamined Patent Application Publication No. 2022-90557).

### BRIEF SUMMARY OF THE DISCLOSURE

In the power amplifier circuit described in Japanese Unexamined Patent Application Publication No. 2022-90557, the wiring layout may cause a change in the output characteristics.

The present disclosure is made in view of the case, and a possible benefit thereof is to provide a power amplifier circuit and a power amplifier device which enable excellent output characteristics to be obtained.

A power amplifier circuit according to an aspect of the present disclosure includes a first carrier amplifier that amplifies a first split signal obtained by splitting a first signal which is one of a pair of balanced signals, and that outputs a first amplified signal from a first output terminal; a first peak amplifier that amplifies a second split signal which is obtained by splitting the first signal and which is different in phase from the first split signal, and that outputs a second amplified signal from a second output terminal; a second carrier amplifier that amplifies a third split signal obtained by splitting a second signal which is the other of the pair of balanced signals, and that outputs a third amplified signal from a third output terminal; a second peak amplifier that amplifies a fourth split signal which is obtained by splitting the second signal and which is different in phase from the third split signal, and that outputs a fourth amplified signal from a fourth output terminal; a first capacitor that has one end connected to the first output terminal and the other end connected to the third output terminal; a second capacitor that has one end connected to the second output terminal and the other end connected to the fourth output terminal; first wiring that has a first end connected to the first output terminal and a second end connected to the second output terminal; second wiring that has a third end connected to the third output terminal and a fourth end connected to the fourth output terminal; a balun that is connected between the first wiring and the second wiring; and third wiring that is electromagnetically coupled to each of the first wiring and the second wiring, and that is connected to a ground. The first wiring is disposed closer to the third wiring than to the second wiring. The second wiring is disposed closer to the third wiring than to the first wiring.

A power amplifier device according to an aspect of the present disclosure is a power amplifier device having the power amplifier circuit described above. The device includes a semiconductor chip that includes the first carrier amplifier, the first peak amplifier, the second carrier amplifier, and the second peak amplifier which are formed thereon or therein; and a board that includes the first wiring, the second wiring, the third wiring, and the balun which are formed therein and that is provided with the semiconductor chip.

The present disclosure may provide a power amplifier circuit and a power amplifier device which enable excellent output characteristics to be obtained.

### BRIEF DESCRIPTION OF THE SEVERAL VIEWS OF THE DRAWINGS

FIG. 1 is a circuit diagram of a power amplifier circuit 101.

FIG. 2 is a schematic diagram illustrating cross sections, which are parallel to the xy plane, of a power amplifier device 11 in which the power amplifier circuit 101 is formed.

FIG. 3 is a schematic perspective view of the power amplifier device 11.

FIG. 4 is a circuit diagram of a power amplifier circuit 102.

FIG. 5 is a schematic diagram illustrating cross sections, which are parallel to the xy plane, of a power amplifier device 12 in which the power amplifier circuit 102 is formed.

FIG. 6 is a schematic diagram illustrating a cross section, which is parallel to the zx plane, of a power amplifier device 13 in which the power amplifier circuit 101 or 102 is formed.

FIG. 7 is a schematic diagram illustrating a cross section, which is parallel to the zx plane, of a power amplifier device 14 in which the power amplifier circuit 101 or 102 is formed.

FIG. 8 is a schematic diagram illustrating a cross section, which is parallel to the zx plane, of a power amplifier device 15 in which the power amplifier circuit 101 or 102 is formed.

### DETAILED DESCRIPTION OF THE DISCLOSURE

Embodiments of the present disclosure will be described below in detail by referring to the drawings. The same components are designated with the same reference numerals, and repeated description will be avoided as much as possible.

### FIRST EMBODIMENT

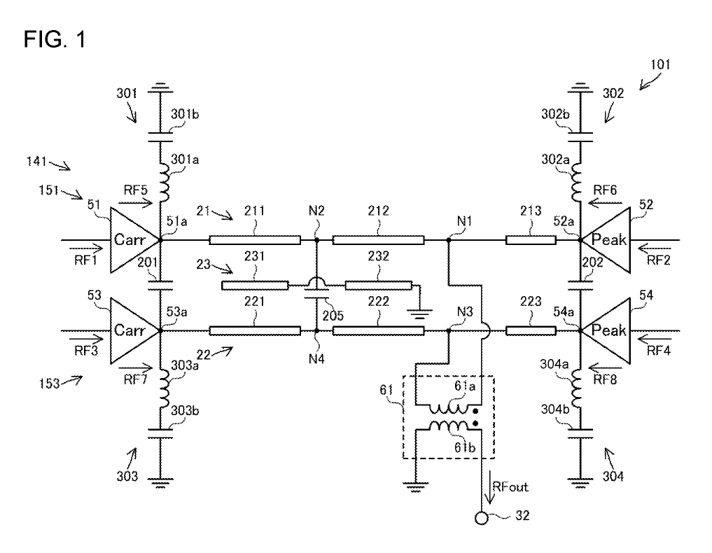

A power amplifier circuit 101 according to a first embodiment will be described. FIG. 1 is a circuit diagram of the power amplifier circuit 101. As illustrated in FIG. 1, the power amplifier circuit 101 includes first wiring 21, second wiring 22, third wiring 23, a balun 61, a differential pair 141, capacitors 201 (first capacitor), 202 (second capacitor), and 205, and harmonic traps 301, 302, 303 and 304.

The differential pair 141 includes Doherty amplifiers 151 and 153. The Doherty amplifier 151 includes a carrier amplifier 51 (first carrier amplifier) and a peak amplifier 52 (first peak amplifier). The Doherty amplifier 153 includes a carrier amplifier 53 (second carrier amplifier) and a peak amplifier 54 (second peak amplifier).

By using the Doherty amplifiers 151 and 153 included in the differential pair 141, the power amplifier circuit 101 amplifies each of one (hereinafter may be referred to as a first signal) of a pair of balanced signals and the other (hereinafter may be referred to as a second signal) of the pair, and outputs an output signal RFout which is a single-ended signal.

Specifically, the first signal and the second signal are signals generated, for example, by a balun (not illustrated) splitting an input signal which is a single-ended signal. The input signal is, for example, a radio frequency (RF) signal.

The phase of the first signal is different from that of the second signal. In the present embodiment, the phase of the first signal is different by approximately 180° from that of the second signal. Imbalance in wire length of a circuit or the like may cause the phase difference between the first signal and the second signal to differ from 180° by a large degree.

The carrier amplifier 51 of the Doherty amplifier 151 in the differential pair 141 amplifies a split signal RF1 (first split signal) obtained by splitting the first signal, and outputs an amplified signal RF5 (first amplified signal) from an output terminal 51a (first output terminal).

The peak amplifier 52 amplifies a split signal RF2 (second split signal), which is obtained by splitting the first signal and which is different in phase from the split signal RF1, and outputs an amplified signal RF6 (second amplified signal) from an output terminal 52a (second output terminal).

The split signals RF1 and RF2 are signals generated, for example, by a splitter (not illustrated) splitting the first signal. The phases of the split signal RF1 and the split signal RF2 which are just outputted from the splitter are, for example, identical.

While the split signal RF2 is supplied to the peak amplifier 52, for example, through a quarter-wavelength line (not illustrated), the split signal RF1 is supplied as it is to the carrier amplifier 51. Therefore, the phase of the split signal RF2 supplied to the peak amplifier 52 is delayed by approximately 90° from the phase of the split signal RF1 supplied to the carrier amplifier 51.

The carrier amplifier 53 of the Doherty amplifier 153 in the differential pair 141 amplifies a split signal RF3 (third split signal) obtained by splitting the second signal, and outputs an amplified signal RF7 (third amplified signal) from an output terminal 53a (third output terminal).

The peak amplifier 54 amplifies a split signal RF4 (fourth split signal), which is obtained by splitting the second signal and which is different in phase from the split signal RF3, and outputs an amplified signal RF8 (fourth amplified signal) from an output terminal 54a (fourth output terminal).

The split signals RF3 and RF4 are signals generated, for example, by a splitter (not illustrated) splitting the second signal. The phases of the split signal RF3 and the split signal RF4 which are just outputted from the splitter are, for example, identical.

While the split signal RF4 is supplied to the peak amplifier 54, for example, through a quarter-wavelength line (not illustrated), the split signal RF3 is supplied as it is to the carrier amplifier 53. Therefore, the phase of the split signal RF4 supplied to the peak amplifier 54 is delayed by approximately 90° from that of the split signal RF3 supplied to the carrier amplifier 53.

The capacitor 201 has one end connected to the output terminal 51a of the carrier amplifier 51 and the other end connected to the output terminal 53a of the carrier amplifier 53. The capacitor 202 has one end connected to the output terminal 52a of the peak amplifier 52 and the other end connected to the output terminal 54a of the peak amplifier 54.

Each of the first wiring 21, the second wiring 22, and the third wiring 23 may be handled as a distributed-constant circuit. That is, each wiring has an inductance per unit length along its extending direction. The wirings have mutual capacitances per unit length along their extending directions.

The first wiring 21 has a first end connected to the output terminal 51a of the carrier amplifier 51 and a second end connected to the output terminal 52a of the peak amplifier 52. In the present embodiment, the first wiring 21 includes wiring lines 211, 212 and 213. The first wiring 21 is provided with a node N1 (first node), which is positioned between the first end and the second end, and a node N2 (second node), which is positioned between the first end and the node N1. The wiring line 211, the wiring line 212, and the wiring line 213 are, for example, electrodes or vias.

The wiring line 211 has one end, that is, the first end, connected to the output terminal 51a of the carrier amplifier 51 and the other end connected to the node N2. The wiring line 212 has one end connected to the node N2 and the other end connected to the node N1. The wiring line 213 has one end connected to the node N1 and the other end, that is, the second end, connected to the output terminal 52a of the peak amplifier 52.

In the present embodiment, the inductance of the wiring line 211 is approximately the same as that of the wiring line 212. The inductance of the wiring line 213 is less than that of the wiring line 211 and that of the wiring line 212.

The second wiring 22 has a third end connected to the output terminal 53a of the carrier amplifier 53 and a fourth end connected to the output terminal 54a of the peak amplifier 54. In the present embodiment, the second wiring 22 includes wiring lines 221, 222, and 223. The second wiring 22 is provided with a node N3 (third node), which is positioned between the third end and the fourth end, and a node N4 (fourth node), which is positioned between the third end and the node N3. The wiring lines 221, 222, and 223 are, for example, electrodes or vias.

The wiring line 221 has one end, that is, the third end, connected to the output terminal 53a of the carrier amplifier 53 and the other end connected to the node N4. The wiring line 222 has one end connected to the node N4 and the other end connected to the node N3. The wiring line 223 has one end connected to the node N3 and the other end, that is, the fourth end, connected to the output terminal 54a of the peak amplifier 54.

In the present embodiment, the inductance of the wiring line 221 is approximately the same as that of the wiring line 222. The inductance of the wiring line 223 is less than that of the wiring line 221 and that of the wiring line 222.

The third wiring 23 is electromagnetically coupled to each of the first wiring 21 and the second wiring 22 and is connected to the ground. In the present embodiment, the third wiring 23 includes wiring lines 231 and 232. The wiring lines 231 and 232 are, for example, electrodes or vias.

The wiring line 231 has one end, which is open, and the other end, and is electromagnetically coupled to each of the wiring lines 211 and 221. The wiring line 232 has one end connected to the other end of the wiring line 231 and the other end connected to the ground and is electromagnetically coupled to each of the wiring lines 212 and 222. That is, the wiring line 231 is electromagnetically coupled to the wiring line 211 and is electromagnetically coupled to the wiring line 221. The wiring line 232 is electromagnetically coupled to the wiring line 212 and is electromagnetically coupled to the wiring line 222.

The configuration in which the other end of the wiring line 232 is connected to the ground is described. However, the configuration is not limited to this. A configuration in which the ground is connected to the one end of the wiring line 232 or between the one end and the other end of the wiring line 232 may be employed. Alternatively, a configuration in which the wiring line 232 is connected to the ground at multiple positions may be employed.

The configuration in which the wiring line 231 is electrically connected to the wiring line 232 is described. However, the configuration is not limited to this. A configuration in which, without electrical connection between the wiring line 231 and the wiring line 232, the wiring line 231 and the wiring line 232 are connected to two separate grounds may be employed. In this case, a configuration in which the ground is connected to the one end or the other end of the wiring line 231, or between the one end and the other end of the wiring line 231 may be employed. Alternatively, a configuration in which the wiring line 231 is connected to the ground at multiple positions may be employed. Alternatively, a configuration in which the wiring lines 231 and 232 forms a single wiring line may be employed.

The first wiring 21 is disposed closer to the third wiring 23 than to the second wiring 22. The second wiring 22 is disposed closer to the third wiring 23 than to the first wiring 21. The layout of the first wiring 21, the second wiring 22, and the third wiring 23 will be described later in detail.

The balun 61 is connected between the first wiring 21 and the second wiring 22. In the present embodiment, the balun 61 is connected between the node N1 and the node N3. Specifically, the balun 61 includes inductors 61a and 61b.

The inductor 61a has one end connected to the node N1 and the other end connected to the node N3. The inductor 61b has one end, from which the output signal RFout is outputted and which is connected to an output terminal 32, and the other end connected to the ground, and is electromagnetically coupled to the inductor 61a.

The harmonic traps 301, 302, 303 and 304 are connected between the ground and the respective output terminals: the output terminal 51a of the carrier amplifier 51; the output terminal 52a of the peak amplifier 52; the output terminal 53a of the carrier amplifier 53; and the output terminal 54a of the peak amplifier 54.

Specifically, the harmonic trap 301 includes an inductor 301a and a capacitor 301b. The inductor 301a has one end connected to the output terminal 51a of the carrier amplifier 51 and the other end. The capacitor 301b has one end connected to the other end of the inductor 301a and the other end connected to the ground.

The harmonic trap 302 includes an inductor 302a and a capacitor 302b. The inductor 302a has one end connected to the output terminal 52a of the peak amplifier 52 and the other end. The capacitor 302b has one end connected to the other end of the inductor 302a and the other end connected to the ground.

The harmonic trap 303 includes an inductor 303a and a capacitor 303b. The inductor 303a has one end connected to the output terminal 53a of the carrier amplifier 53 and the other end. The capacitor 303b has one end connected to the other end of the inductor 303a and the other end connected to the ground.

The harmonic trap 304 includes an inductor 304a and a capacitor 304b. The inductor 304a has one end connected to the output terminal 54a of the peak amplifier 54 and the other end. The capacitor 304b has one end connected to the other end of the inductor 304a and the other end connected to the ground.

The capacitor 205 has one end connected to the node N2 and the other end connected to the node N4.

Each drawing may illustrate the x-axis, the y-axis, and the z-axis. The x-axis, the y-axis, and the z-axis form right-handed three-dimensional rectangular coordinates. Hereinafter, the arrow direction of the x-axis may be referred to as the positive x-axis side; the opposite direction of the arrow may be referred to as the negative x-axis side. The same is true for the other axes. The positive z-axis side and the negative z-axis side may be referred to as the "upper side" and the "lower side", respectively. The z-axis direction may be referred to as the "laminating direction". The plane orthogonal to the x-axis may be referred to as the yz plane; the plane orthogonal to the y-axis, as the zx plane; the plane orthogonal to the z-axis, as the xy plane. The clockwise rotating direction viewed from the upper side to the lower side is defined as the clockwise direction cw. The counterclockwise rotating direction viewed from the upper side to the lower side is defined as the counterclockwise direction ccw.

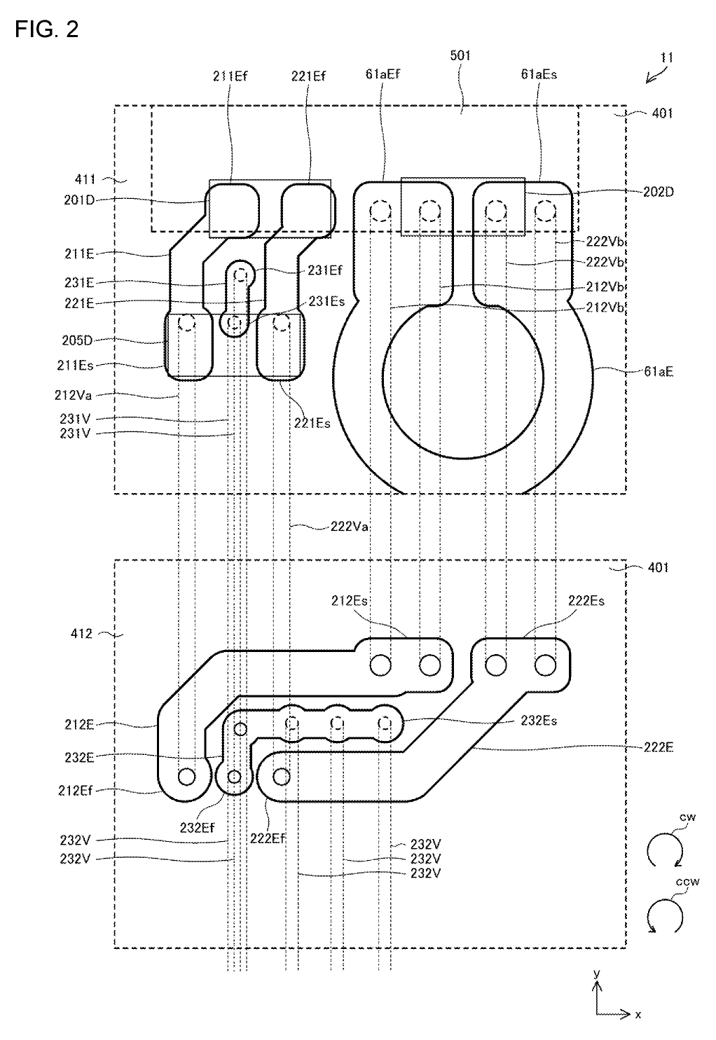

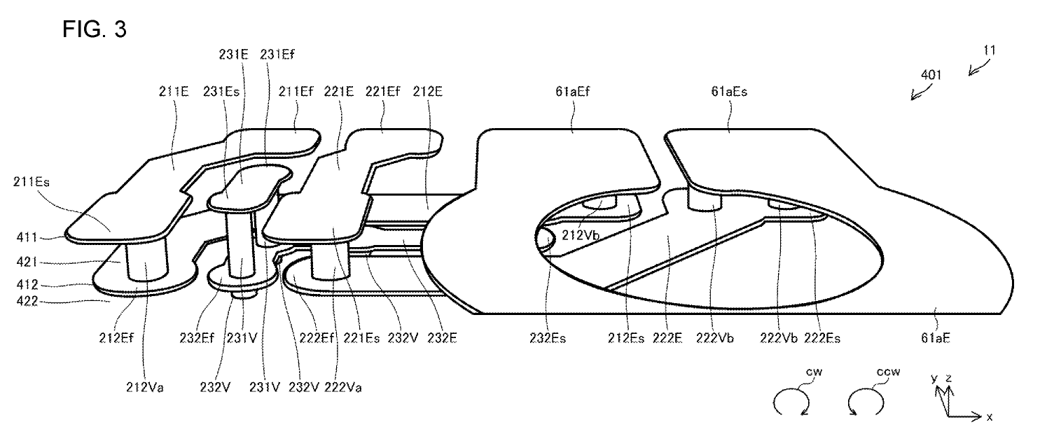

FIG. 2 is a schematic diagram illustrating cross sections, which are parallel to the xy plane, of a power amplifier device 11 in which the power amplifier circuit 101 is formed. FIG. 3 is a schematic perspective view of the power amplifier device 11.

As illustrated in FIGS. 2 and 3, the power amplifier device 11 includes a multilayer board 401 and a semiconductor chip 501. The multilayer board 401 includes conductive layers 411 (first conductive layer) and 412 (second conductive layer) and dielectric layers 421 and 422. The dielectric layers 421 and 422 are disposed in this order from the upper side toward the lower side.

Each of the dielectric layers 421 and 422 has a surface (hereinafter may be referred to as the upper-side surface), which is substantially parallel to the xy plane and which faces the upper side, and a surface (hereinafter may be referred to as the lower-side surface), which is approximately parallel to the xy plane and which faces the lower side. The upper-side surface of the dielectric layer 422 is opposite to the lower-side surface of the dielectric layer 421 which is positioned above the dielectric layer 422. The same is true for other dielectric layers. The upper-side surface and the lower-side surface may have irregularities generated in manufacturing, recesses for disposing a wiring layer, or the like.

The conductive layer 411 is disposed on the upper-side surface of the dielectric layer 421. The conductive layer 412 is disposed on the upper-side surface of the dielectric layer 422.

The conductive layer 411 includes a part of the first wiring 21, a part of the second wiring 22, and a part of the third wiring 23. The conductive layer 412 includes another part of the first wiring 21, another part of the second wiring 22, and another part of the third wiring 23.

Specifically, the first wiring 21, the second wiring 22, the third wiring 23, and the balun 61 are formed in the multilayer board 401. The carrier amplifier 51, the peak amplifier 52, the carrier amplifier 53, and the peak amplifier 54 (which are not illustrated) are formed in or on the semiconductor chip 501.

Electrodes 211E, 221E, 231E, and 61aE are formed in the conductive layer 411. Electrodes 212E, 222E, and 232E are formed in the conductive layer 412.

Vias 212Va, 212Vb, 222Va, 222Vb, and 231V which extend in the laminating direction are formed in the dielectric layer 421. Vias 232V extending in the laminating direction are formed in the dielectric layer 422.

The electrode 211E in the conductive layer 411 has an end portion 211Ef, which is electrically connected to the output terminal 51a of the carrier amplifier 51, and an end portion 211Es, which is connected to an upper end portion of the via 212Va.

When the power amplifier device 11 is viewed from the upper side, the electrode 211E has a shape in which the electrode 211E extends from the end portion 211Ef to the end portion 211Es while its extending direction changes (see FIGS. 2 and 3).

In the present embodiment, when the xy plane is viewed in a state in which the directions toward the positive y-axis side, the positive x-axis side, the negative y-axis side, and the negative x-axis side are defined as the north, the east, the south, and the west, respectively, the electrode 211E extends from the end portion 211Ef to the end portion 211Es while its extending direction changes from the southwest direction to the south direction. The electrode 211E functions as the wiring line 211 in the power amplifier circuit 101.

The electrode 221E has an end portion 221Ef, which is electrically connected to the output terminal 53a of the carrier amplifier 53, and an end portion 221Es, which is connected to an upper end portion of the via 222Va.

The end portions 221Ef and 221Es of the electrode 221E are located on the positive x-axis side relative to the end portions 211Ef and 211Es of the electrode 211E, respectively.

When the power amplifier device 11 is viewed from the upper side, the electrode 221E has a shape in which the electrode 221E extends from the end portion 221Ef to the end portion 221Es while its extending direction changes (see FIGS. 2 and 3).

In the present embodiment, the electrode 221E extends from the end portion 221Ef to the end portion 221Es while its extending direction changes from the southwest direction to the south direction. The electrode 221E functions as the wiring line 221 in the power amplifier circuit 101.

The end portions 211Ef and 221Ef are connected, on their upper sides, to a component 201D which functions as the capacitor 201 in the power amplifier circuit 101 (see FIG. 2).

The end portions 211Es and 221Es are connected, on their upper sides, a component 205D which functions as the capacitor 205 in the power amplifier circuit 101 (see FIG. 2). The components 201D and 205D are, for example, surface mount devices (SMDs).

The end portions 211Es and 221Es correspond to the nodes N2 and N4 in the power amplifier circuit 101, respectively.

The electrode 231E is disposed between the electrode 211E and the electrode 221E. The electrode 231E extends along the y-axis. The electrode 231E functions as the wiring line 231 in the power amplifier circuit 101.

An end portion 231Ef of the electrode 231E on the positive y-axis side is positioned on the negative y-axis side relative to the end portion 211Ef of the electrode 211E and the end portion 221Ef of the electrode 221E. An end portion 231Es of the electrode 231E on the negative y-axis side is positioned on the positive y-axis side relative to the end portion 211Es of the electrode 211E and the end portion 221Es of the electrode 221E. The length of the electrode 231E is shorter than that of the electrode 211E and that of the electrode 212E.

The end portion 231Ef and the end portion 231Es of the electrode 231E are connected to upper end portions of the respective two vias 231V.

The electrode 61aE is located on the positive x-axis side relative to the electrode 221E and is wound in the plane in which the conductive layer 411 extends. Specifically, the electrode 61aE has an end portion 61aEf on the negative x-axis side and an end portion 61aEs on the positive x-axis side, which are electrically connected to the output terminal 52a of the peak amplifier 52 and the output terminal 54a of the peak amplifier 54, respectively.

The end portion 61aEf of the electrode 61aE is positioned on the positive x-axis side relative to the end portion 221Ef of the electrode 221E and is connected to upper end portions of the two vias 212Vb.

The end portion 61aEs of the electrode 61aE is positioned on the positive x-axis side relative to the end portion 61aEf and is connected to upper end portions of the two vias 222Vb.

When the power amplifier device 11 is viewed from the upper side, the electrode 61aE is wound from the end portion 61aEf to the end portion 61aEs by an amount equal to or greater than three-fourths of a turn and less than one turn in the counterclockwise direction ccw in the xy plane.

The end portions 61aEf and 61aEs are connected, on their upper sides, to a component 202D which functions as the capacitor 202 in the power amplifier circuit 101 (see FIG. 2). The component 202D is, for example, a surface mount device.

The end portions 61aEf and 61aEs correspond to the nodes N1 and N3 in the power amplifier circuit 101, respectively.

The electrode 212E in the conductive layer 412 has an end portion 212Ef, which is connected to a lower end portion of the via 212Va, and an end portion 212Es, which is connected to lower end portions of the two vias 212Vb. The electrode 212E and the vias 212Va and 212Vb function as the wiring line 212 in the power amplifier circuit 101.

When the power amplifier device 11 is viewed from the upper side, the electrode 212E has a shape in which the electrode 212E extends from the end portion 212Ef to the end portion 212Es while its extending direction changes (see FIGS. 2 and 3).

In the present embodiment, the electrode 212E extends from the end portion 212Ef to the end portion 212Es while its extending direction changes from the north direction to the northeast direction, and then to the east direction.

The electrode 222E has an end portion 222Ef, which is connected to a lower end portion of the via 222Va, and an end portion 222Es, which is connected to lower end portions of the two vias 222Vb. The electrode 222E and the vias 222Va and 222Vb function as the wiring line 222 in the power amplifier circuit 101.

When the power amplifier device 11 is viewed from the upper side, the electrode 222E has a shape in which the electrode 222E extends from the end portion 222Ef to the end portion 222Es while its extending direction changes (see FIGS. 2 and 3).

In the present embodiment, the electrode 222E extends from the end portion 222Ef to the end portion 222Es while its extending direction changes from the east direction to the northeast direction.

The electrode 232E is disposed between the electrode 212E and the electrode 222E. An end portion 232Ef of the electrode 232E is positioned between the end portion 212Ef of the electrode 212E and the end portion 222Ef of the electrode 222E. The electrode 232E functions as the wiring line 232 in the power amplifier circuit 101.

When the power amplifier device 11 is viewed from the upper side, the electrode 232E has a shape in which the electrode 232E extends from the end portion 232Ef to an end portion 232Es while its extending direction changes (see FIGS. 2 and 3).

In the present embodiment, the electrode 232E extends from the end portion 232Ef to the end portion 232Es while its extending direction changes from the north direction to the east direction.

The upper-side surface of the electrode 232E is connected to lower end portions of the two vias 231V. The lower-side surface of the electrode 232E is connected to the ground through five vias 232V.

### Effects

If, in a configuration without the third wiring 23, the first wiring 21 is disposed close to the second wiring 22, the electromagnetic coupling between the first wiring 21 and the second wiring 22 increases. Therefore, when output from the Doherty amplifier 151 and output from the Doherty amplifier 153 in the differential pair 141 are transmitted to the first wiring 21 and the second wiring 22, respectively, the inductance of the first wiring 21 and that of the second wiring 22 decrease, and the impedance viewed from the Doherty amplifier 151 and that viewed from the Doherty amplifier 153 change. Therefore, the output-signal characteristics change.

In contrast, in the power amplifier circuit 101, the first wiring 21 is disposed closer to the third wiring 23 than to the second wiring 22; the second wiring 22 is disposed closer to the third wiring 23 than to the first wiring 21; the third wiring 23 is connected to the ground. This configuration enables suppression of electromagnetic coupling between the first wiring 21 and the second wiring 22. This achieves suppression of the reduction in the inductance of the first wiring 21 and the second wiring 22, thereby suppressing the change in the output-signal characteristics. The change is caused by the change in the impedance viewed from the Doherty amplifier 151 and that viewed from the Doherty amplifier 153.

The configuration in which each of the first wiring 21, the second wiring 22, and the third wiring 23 is formed in the two layers of the conductive layer 411 and the conductive layer 412 is described. However, the configuration is not limited to this. Each of the first wiring 21, the second wiring 22, and the third wiring 23 may be formed in a single conductive layer or may be formed in three or more conductive layers.

### SECOND EMBODIMENT

A power amplifier circuit 102 according to a second embodiment will be described. In the second embodiment and its subsequent embodiments, points common to those in the first embodiment will not be described, and only different points will be described. In particular, substantially the same operational effects due to substantially the same configuration will not be described in each embodiment.

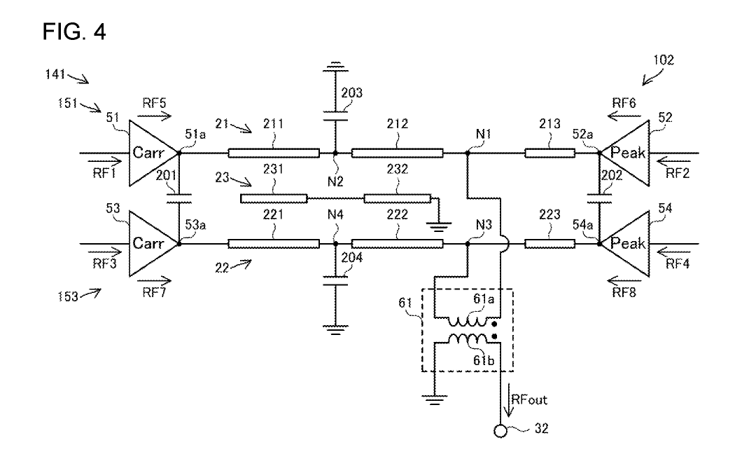

FIG. 4 is a circuit diagram of the power amplifier circuit 102. As illustrated in FIG. 4, the power amplifier circuit 102 is different from the power amplifier circuit 101 according to the first embodiment in that capacitors 203 and 204 are included instead of the capacitor 205 and the harmonic traps 301, 302, 303 and 304.

The capacitor 203 has one end connected to the node N2 and the other end connected to the ground. The capacitor 204 has one end connected to the node N4 and the other end connected to the ground.

In the present embodiment, the inductance of the wiring line 211 is approximately the same as that of the wiring line 212. The inductance of the wiring line 221 is approximately the same as that of the wiring line 222.

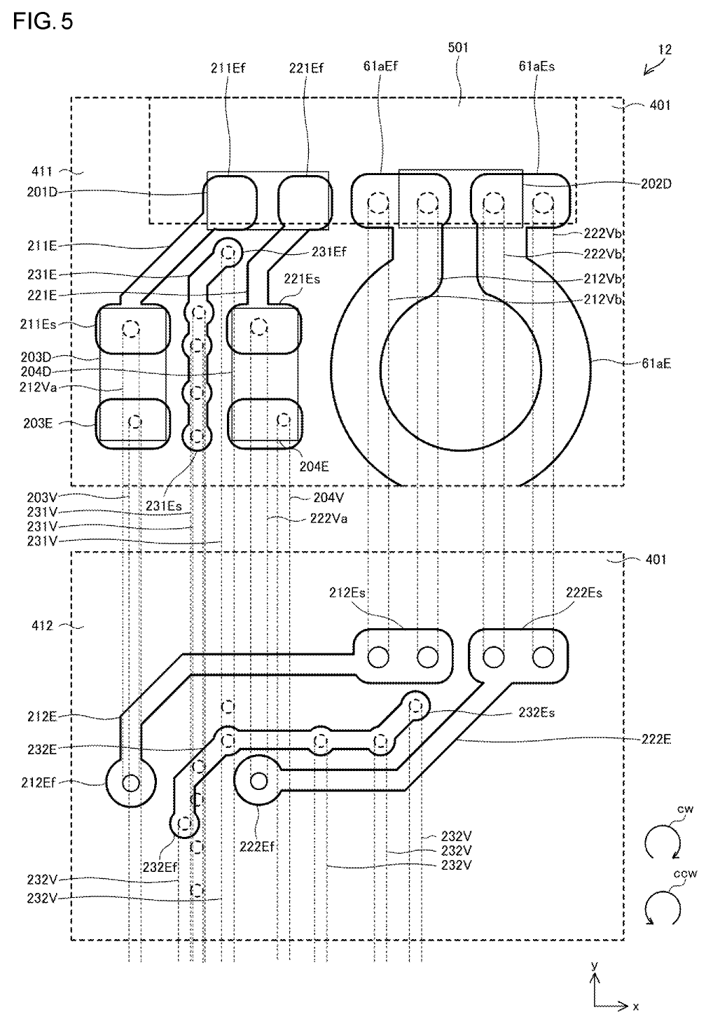

FIG. 5 is a schematic diagram illustrating cross sections, which are parallel to the xy plane, of a power amplifier device 12 in which the power amplifier circuit 102 is formed.

As illustrated in FIG. 5, the conductive layer 411 of the power amplifier device 12 includes additionally-formed electrodes 203E and 204E, compared with the conductive layer 411 illustrated in FIGS. 2 and 3.

The electrode 203E, which is, for example, a pad, is located on the negative y-axis side relative to the end portion 211Es of the electrode 211E. The electrode 203E is electrically connected to the ground through a via 203V.

The electrode 203E and the end portion 211Es are connected, on their upper sides, to a component 203D which functions as the capacitor 203 in the power amplifier circuit 102. The component 203D is, for example, a surface mount device.

The electrode 204E, which is, for example, a pad, is located on the negative y-axis side relative to the end portion 221Es of the electrode 221E and on the positive x-axis side relative to the electrode 203E. The electrode 204E is electrically connected to the ground through a via 204V.

The electrode 204E and the end portion 221Es are connected, on their upper sides, to a component 204D which functions as the capacitor 204 in the power amplifier circuit 102. The component 204D is, for example, a surface mount device.

When the power amplifier device 12 is viewed from the upper side, the electrode 231E has a shape in which the electrode 231E extends from the end portion 231Ef to the end portion 231Es while its extending direction changes.

In the present embodiment, the electrode 231E extends from the end portion 231Ef to the end portion 231Es while its extending direction changes from the southwest direction to the south direction.

When the power amplifier device 12 is viewed from the upper side, the electrode 232E in the conductive layer 412 has a shape in which the electrode 232E extends from the end portion 232Ef to the end portion 232Es while its extending direction changes.

In the present embodiment, the electrode 232E extends from the end portion 232Ef to the end portion 232Es while its extending direction changes from the north direction to the northeast direction, then to the east direction, and then to the northeast direction.

### THIRD EMBODIMENT

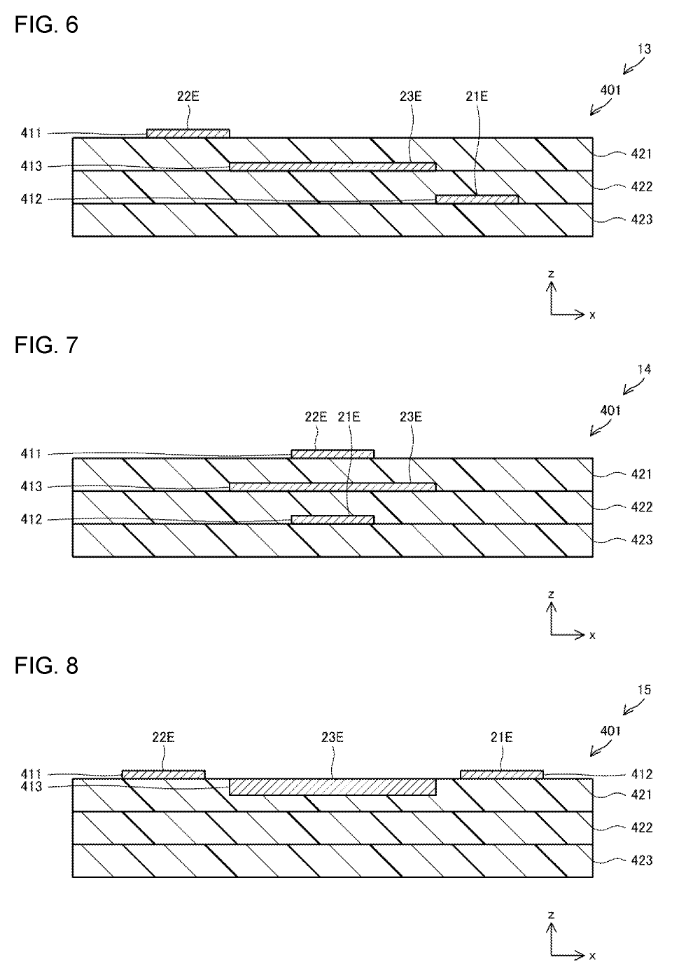

A power amplifier device 13 according to a third embodiment will be described. FIG. 6 is a schematic diagram illustrating a cross section, which is parallel to the zx plane, of the power amplifier device 13 in which the power amplifier circuit 101 or 102 is formed.

In the power amplifier devices 11 and 12, the configuration in which the electrode 211E, the electrode 221E, and the electrode 231E are disposed in the conductive layer 411 and in which the electrode 212E, the electrode 222E, and the electrode 232E are disposed in the conductive layer 412 is described. However, the configuration is not limited to this. A configuration in which the first wiring 21, the second wiring 22, and the third wiring 23 are disposed in different conductive layers, respectively, may be employed.

In the present embodiment, the multilayer board 401 of the power amplifier device 13 includes conductive layers 411, 412, and 413 (third conductive layer) and dielectric layers 421, 422, and 423. The dielectric layers 421, 422, and 423 are disposed in this order from the upper side to the lower side.

The conductive layer 413 is positioned between the conductive layer 411 and the conductive layer 412. Specifically, the conductive layer 411 is disposed on the upper-side surface of the dielectric layer 421. The conductive layer 413 is disposed on the upper-side surface of the dielectric layer 422. The conductive layer 412 is disposed on the upper-side surface of the dielectric layer 423.

The first wiring 21, the second wiring 22, and the third wiring 23 are disposed in a conductive layer 412, a conductive layer 411, and a conductive layer 413, respectively.

Specifically, the conductive layer 411 includes an electrode 22E functioning as the second wiring 22. The conductive layer 412 includes an electrode 21E functioning as the first wiring 21. The conductive layer 413 includes an electrode 23E functioning as the third wiring 23.

In the power amplifier device 13, the electrode 22E does not overlap the electrode 21E when the power amplifier device 13 is viewed from the upper side. Specifically, the electrode 21E is positioned on the lower side and the positive x-axis side relative to the electrode 22E. The electrode 23E is positioned between the electrode 22E and the electrode 21E.

### FOURTH EMBODIMENT

A power amplifier device 14 according to a fourth embodiment will be described. FIG. 7 is a schematic diagram illustrating a cross section, which is parallel to the zx plane, of the power amplifier device 14 in which the power amplifier circuit 101 or 102 is formed.

As illustrated in FIG. 7, the power amplifier device 14 according to the fourth embodiment is different from the power amplifier device 13 according to the third embodiment in that the electrode 22E overlaps the electrode 21E when the power amplifier device 14 is viewed from the upper side.

Specifically, the electrode 21E is positioned on the lower side relative to the electrode 22E. The electrode 23E is positioned between the electrode 22E and the electrode 21E.

### FIFTH EMBODIMENT

A power amplifier device 15 according to a fifth embodiment will be described. FIG. 8 is a schematic diagram illustrating a cross section, which is parallel to the zx plane, of the power amplifier device 15 in which the power amplifier circuit 101 or 102 is formed.

As illustrated in FIG. 8, the power amplifier device 15 according to the fifth embodiment is different from the power amplifier device 13 according to the third embodiment and the power amplifier device 14 according to the fourth embodiment in that the electrode 23E is not disposed between the electrode 21E and the electrode 22E.

In the power amplifier device 15, the electrode 21E is disposed closer to the electrode 23E than to the electrode 22E. That is, the distance between the electrode 21E and the electrode 23E is shorter than that between the electrode 21E and the electrode 22E.

The electrode 22E is disposed closer to the electrode 23E than to the electrode 21E. That is, the distance between the electrode 22E and the electrode 23E is shorter than that between the electrode 22E and the electrode 21E.

Specifically, the electrode 22E is disposed on the upper-side surface of the dielectric layer 421. The electrode 23E is positioned on the lower side and the positive x-axis side relative to the electrode 22E and is embedded on the lower side relative to the upper-side surface of the dielectric layer 421. The electrode 21E is positioned on the upper side and the positive x-axis side relative to the electrode 23E and is disposed on the upper-side surface of the dielectric layer 421.

In the present embodiment, the configuration in which the third wiring 23 is not disposed between the wiring line 213 and the wiring line 223 is described. However, the configuration is not limited to this. A configuration in which the third wiring 23 is disposed between the wiring line 213 and the wiring line 223 may be employed.

Like the electrode 232E illustrated in FIG. 2, the third wiring 23 may be disposed at a position where the first wiring 21 is the closest to the second wiring 22.

The embodiment examples of the present disclosure are described above. In the power amplifier circuits 101 and 102, the carrier amplifier 51 amplifies the split signal RF1 obtained by splitting the first signal which is one of a pair of balanced signals, and outputs the amplified signal RF5 from the output terminal 51a. The peak amplifier 52 amplifies the split signal RF2 which is obtained by splitting the first signal and which is different in phase from the split signal RF1, and outputs the amplified signal RF6 from the output terminal 52a. The carrier amplifier 53 amplifies the split signal RF3 obtained by splitting the second signal which is the other of the pair of balanced signals, and outputs the amplified signal RF7 from the output terminal 53a. The peak amplifier 54 amplifies the split signal RF4 which is obtained by splitting the second signal and which is different in phase from the split signal RF3, and outputs the amplified signal RF8 from the output terminal 54a. The capacitor 201 has the one end connected to the output terminal 51a and the other end connected to the output terminal 53a. The capacitor 202 has the one end connected to the output terminal 52a and the other end connected to the output terminal 54a. The first wiring 21 has the first end connected to the output terminal 51a and the second end connected to the output terminal 52a. The second wiring 22 has the third end connected to the output terminal 53a and the fourth end connected to the output terminal 54a. The balun 61 is connected between the first wiring 21 and the second wiring 22. The third wiring 23 is electromagnetically coupled to each of the first wiring 21 and the second wiring 22 and is connected to the ground. The first wiring 21 is disposed closer to the third wiring 23 than to the second wiring 22. The second wiring 22 is disposed closer to the third wiring 23 than to the first wiring 21.

Thus, the first wiring 21 is disposed closer to the third wiring 23 than to the second wiring 22; the second wiring 22 is disposed closer to the third wiring 23 than to the first wiring 21; the third wiring 23 is connected to the ground. This configuration suppresses electromagnetic coupling between the first wiring 21 and the second wiring 22, thereby suppressing a reduction in the inductance of the first wiring 21 and the second wiring 22 and suppressing excessive current flowing through the first wiring 21 and the second wiring 22. Therefore, a power amplifier circuit which achieves excellent output characteristics may be provided.

In addition, in the power amplifier circuit 102, the first wiring 21 is provided with the node N1 positioned between the first end and the second end and the node N2 positioned between the first end and the node N1. The second wiring 22 is provided with the node N3 positioned between the third end and the fourth end and the node N4 positioned between the third end and the node N3. The balun 61 is connected between the nodes N1 and N3. The capacitor 203 has the one end connected to the node N2 and the other end connected to the ground. The capacitor 204 has the one end connected to the node N4 and the other end connected to the ground.

The configuration of the capacitor 201, the wiring line 211 having an inductance, the capacitor 203, the wiring line 212 having an inductance, and the capacitor 202 may function as a quarter-wavelength line for the fundamental wave. Similarly, the configuration of the capacitor 201, the wiring line 221 having an inductance, the capacitor 204, the wiring line 222 having an inductance, and the capacitor 202 may function as a quarter-wavelength line for the fundamental wave. As seen from the carrier amplifier 51 to the peak amplifier 52, the configuration of the wiring line 211 and the capacitor 203 may function as a series LC resonant circuit for the second harmonic. Thus, a termination circuit for the second harmonic, which is like the harmonic trap 301 in the power amplifier circuit 101, may be implemented with a small circuit size. The configuration of the wiring line 221 and the capacitor 204 also has substantially the same effects as those of the configuration of the wiring line 211 and the capacitor 203. As seen from the peak amplifier 52 to the carrier amplifier 51, the configuration of the wiring line 212 and the capacitor 203 may function as a series LC resonant circuit for the second harmonic. Thus, a termination circuit for the second harmonic, which is like the harmonic trap 302 in the power amplifier circuit 101, may be implemented with a circuit size. The configuration of the wiring line 222 and the capacitor 204 also have substantially the same effects as those of the configuration of the wiring line 212 and the capacitor 203.

In addition, in the power amplifier circuits 101 and 102, the third wiring 23 is disposed between the first wiring 21 and the second wiring 22.

This configuration enables the third wiring 23 to be disposed so that viewing the second wiring 22 from the first wiring 21 is blocked, achieving effective suppression of electromagnetic coupling between the first wiring 21 and the second wiring 22.

In addition, in the power amplifier circuits 101 and 102, the first wiring 21 is provided with the node N1 positioned between the first end and the second end. The second wiring 22 is provided with the node N3 positioned between the third end and the fourth end. The balun 61 is connected between the nodes N1 and N3. The third wiring 23 is disposed between at least a part of the first wiring 21 from the first end to the node N1 and at least a part of the second wiring 22 from the third end to the node N3.

The first wiring 21 from the first end to the node N1 and the second wiring 22 from the third end to the node N3 function as a quarter-wavelength line. The long line length easily causes the electromagnetic coupling between the first wiring 21 and the second wiring 22 to increase. In contrast, the configuration in which the third wiring 23 is disposed between at least a part of the first wiring 21 from the first end to the node N1 and at least a part of the second wiring 22 from the third end to the node N3 achieves effective suppression of electromagnetic coupling between the first wiring 21 and the second wiring 22.

In addition, in the power amplifier devices 11 to 15, the semiconductor chip 501 includes the carrier amplifier 51, the peak amplifier 52, the carrier amplifier 53, and the peak amplifier 54 which are formed thereon or therein. The multilayer board 401 includes the first wiring 21, the second wiring 22, the third wiring 23, and the balun 61 which are formed therein, and is provided with the semiconductor chip 501.

Thus, the configuration in which the first wiring 21, the second wiring 22, the third wiring 23, and the balun 61, which have large circuit sizes, are formed in the multilayer board 401 improves a range of choices of layout of the first wiring 21, the second wiring 22, the third wiring 23, and the balun 61. This easily achieves a layout for the third wiring 23 effectively suppressing electromagnetic coupling between the first wiring 21 and the second wiring 22.

In addition, in the power amplifier devices 11 and 12, the multilayer board 401 includes the conductive layer 411. At least a part of the first wiring 21, at least a part of the second wiring 22, and at least a part of the third wiring 23 are disposed in the conductive layer 411.

According to this configuration, for example, in the case where the output terminal 51a of the carrier amplifier 51 and the output terminal 53a of the carrier amplifier 53 are disposed in the same conductive layer and where the first wiring 21 and the second wiring 22 are routed in the wiring layer, such a layout of the third wiring 23 that, for example, viewing the second wiring 22 from the first wiring 21 is blocked may be easily implemented through routing of the wiring lines.

In addition, in the power amplifier devices 13 and 14, the multilayer board 401 includes the conductive layer 411, the conductive layer 412, and the conductive layer 413 which is located between the conductive layers 411 and 412. The first wiring 21, the second wiring 22, and the third wiring 23 are disposed in the conductive layers 412, 411, and 413, respectively.

According to this configuration, for example, in the case where the output terminal 51a of the carrier amplifier 51 and the output terminal 53a of the carrier amplifier 53 are disposed in the conductive layers 412 and 411, respectively, and where the first wiring 21 and the second wiring 22 are routed in the respective different wiring layers, such a layout of the third wiring 23 that, for example, viewing the second wiring 22 from the first wiring 21 is blocked may be easily implemented through routing of the wiring lines.

The embodiments described above are made for facilitating understanding of the present disclosure, not for limitedly interpreting the present disclosure. The present disclosure may be changed/improved without departing from its gist, and the present disclosure encompasses its equivalents. That is, embodiments obtained by those skilled in the art appropriately adding changes in design to the embodiments are also encompassed in the scope of the present disclosure as long as they have features of the present disclosure. For example, the components included in the embodiments and their layout, materials, conditions, shapes, sizes, and the like are not limited to those illustrated, and may be changed appropriately. The embodiments are examples. Needless to say, partial replacement or combination of the configurations illustrated in different embodiments may be made. These are encompassed in the scope of the present disclosure as long as they have features of the present disclosure.

<1> A power amplifier circuit comprising: a first carrier amplifier that amplifies a first split signal obtained by splitting a first signal which is one of a pair of balanced signals, and that outputs a first amplified signal from a first output terminal; a first peak amplifier that amplifies a second split signal which is obtained by splitting the first signal and which is different in phase from the first split signal, and that outputs a second amplified signal from a second output terminal; a second carrier amplifier that amplifies a third split signal obtained by splitting a second signal which is the other of the pair of balanced signals, and that outputs a third amplified signal from a third output terminal; a second peak amplifier that amplifies a fourth split signal which is obtained by splitting the second signal and which is different in phase from the third split signal, and that outputs a fourth amplified signal from a fourth output terminal; a first capacitor that has one end connected to the first output terminal and the other end connected to the third output terminal; a second capacitor that has one end connected to the second output terminal and the other end connected to the fourth output terminal; first wiring that has a first end connected to the first output terminal and a second end connected to the second output terminal; second wiring that has a third end connected to the third output terminal and a fourth end connected to the fourth output terminal; a balun that is connected between the first wiring and the second wiring; and third wiring that is electromagnetically coupled to each of the first wiring and the second wiring, and that is connected to a ground, wherein the first wiring is disposed closer to the third wiring than to the second wiring, and wherein the second wiring is disposed closer to the third wiring than to the first wiring.

<2> The power amplifier circuit according to <1>, wherein the first wiring is provided with a first node positioned between the first end and the second end and a second node positioned between the first end and the first node, wherein the second wiring is provided with a third node positioned between the third end and the fourth end and a fourth node positioned between the third end and the third node, wherein the balun is connected between the first node and the third node, and wherein the power amplifier circuit further comprises: a third capacitor that has one end connected to the second node and the other end connected to a ground, and a fourth capacitor that has one end connected to the fourth node and the other end connected to a ground.

<3> The power amplifier circuit according to <1> or <2>, wherein the third wiring is disposed between the first wiring and the second wiring.

<4> The power amplifier circuit according to any one of <1> to <3>, wherein the first wiring is provided with a first node positioned between the first end and the second end, wherein the second wiring is provided with a third node positioned between the third end and the fourth end, wherein the balun is connected between the first node and the third node, and wherein the third wiring is disposed between at least a part of the first wiring from the first end to the first node and at least a part of the second wiring from the third end to the third node.

<5> A power amplifier device having the power amplifier circuit according to any one of <1> to <4>, the device comprising: a semiconductor chip that includes the first carrier amplifier, the first peak amplifier, the second carrier amplifier, and the second peak amplifier which are formed thereon or therein; and a board that includes the first wiring, the second wiring, the third wiring, and the balun which are formed therein and that is provided with the semiconductor chip.

<6> The power amplifier device according to <5>, wherein the board includes a first conductive layer, and wherein at least a part of the first wiring, at least a part of the second wiring, and at least a part of the third wiring are disposed in the first conductive layer.

<7> The power amplifier device according to <5> , wherein the board includes a first conductive layer, a second conductive layer, and a third conductive layer between the first conductive layer and the second conductive layer, and wherein the first wiring, the second wiring, and the third wiring are disposed in the first conductive layer, the second conductive layer, and the third conductive layer, respectively.

<A> A power amplifier circuit comprising: a first carrier amplifier that amplifies a first split signal obtained by splitting a first signal which is one of a pair of balanced signals, and that outputs a first amplified signal from a first output terminal; a first peak amplifier that amplifies a second split signal which is obtained by

splitting the first signal and which is different in phase from the first split signal, and that outputs a second amplified signal from a second output terminal; a second carrier amplifier that amplifies a third split signal obtained by splitting a second signal which is the other of the pair of balanced signals, and that outputs a third amplified signal from a third output terminal; a second peak amplifier that amplifies a fourth split signal which is obtained by splitting the second signal and which is different in phase from the third split signal, and that outputs a fourth amplified signal from a fourth output terminal; a first capacitor that has one end connected to the first output terminal and the other end connected to the third output terminal; a second capacitor that has one end connected to the second output terminal and the other end connected to the fourth output terminal; first wiring that has a first end connected to the first output terminal and a second end connected to the second output terminal; second wiring that has a third end connected to the third output terminal and a fourth end connected to the fourth output terminal; a balun that is connected between the first wiring and the second wiring; and third wiring that is electromagnetically coupled to each of the first wiring and the second wiring, and that is connected to a ground, wherein the first wiring is provided with a first node

positioned between the first end and the second end and a second node positioned between the first end and the first node, wherein the second wiring is provided with a third node positioned between the third end and the fourth end and a fourth node positioned between the third end and the third node, wherein the balun is connected between the first node and the third node, and wherein the power amplifier circuit further comprises: a third capacitor that has one end connected to the second node and the other end connected to a ground, and a fourth capacitor that has one end connected to the fourth node and the other end connected to a ground.

11, 12, 13, 14, 15 power amplifier device

21 first wiring

211, 212, 213 wiring line

21E, 211E electrode

212E electrode

212Va, 212Vb via

22 second wiring

221, 222, 223 wiring line

22E, 221E, 222E electrode

222Va, 222Vb via

23 third wiring

231, 232 wiring line

23E, 231E, 232E electrode

231V, 232V via

32 output terminal

51, 53 carrier amplifier

52, 54 peak amplifier

51a, 52a, 53a, 54a output terminal

61 balun

61a, 61b inductor

61aE electrode

101, 102 power amplifier circuit

141 differential pair

151, 153 Doherty amplifier

201, 202, 203, 204, 205 capacitor

201D, 202D, 203D, 204D, 205D component

203E, 204E electrode

203V, 204V via

301, 302, 303, 304 harmonic trap

401 multilayer board

411, 412, 413 conductive layer

421, 422, 423 dielectric layer

501 semiconductor chip

N1, N2, N3, N4 node

1. A power amplifier circuit comprising:
a first carrier amplifier configured to amplify a first split signal obtained by splitting a first signal which is one of a pair of balanced signals, and to output a first amplified signal from a first output terminal;
a first peak amplifier configured to amplify a second split signal which is obtained by splitting the first signal and which is different in phase from the first split signal, and to output a second amplified signal from a second output terminal;
a second carrier amplifier configured to amplify a third split signal obtained by splitting a second signal which is the other of the pair of balanced signals, and to output a third amplified signal from a third output terminal;
a second peak amplifier configured to amplify a fourth split signal which is obtained by splitting the second signal and which is different in phase from the third split signal, and to output a fourth amplified signal from a fourth output terminal;
a first capacitor that has a first end connected to the first output terminal and a second end connected to the third output terminal;
a second capacitor that has a first end connected to the second output terminal and a second end connected to the fourth output terminal;
first wiring that has a first end connected to the first output terminal and a second end connected to the second output terminal;
second wiring that has a third end connected to the third output terminal and a fourth end connected to the fourth output terminal;
a balun that is connected between the first wiring and the second wiring; and
third wiring that is electromagnetically coupled to each of the first wiring and the second wiring, and that is connected to ground,
wherein the first wiring is closer to the third wiring than to the second wiring, and
wherein the second wiring is closer to the third wiring than to the first wiring.

2. The power amplifier circuit according to claim 1,
wherein the first wiring has a first node between the first end and the second, end and a second node between the first end and the first node,
wherein the second wiring has a third node between the third end and the fourth end, and a fourth node between the third end and the third node,
wherein the balun is connected between the first node and the third node, and
wherein the power amplifier circuit further comprises:
a third capacitor that has a first end connected to the second node and a second end connected to ground, and
a fourth capacitor that has a first end connected to the fourth node and a second end connected to ground.

3. The power amplifier circuit according to claim 1, wherein the third wiring is between the first wiring and the second wiring.

4. The power amplifier circuit according to claim 1,
wherein the first wiring has a first node between the first end and the second end,
wherein the second wiring has a third node between the third end and the fourth end,
wherein the balun is connected between the first node and the third node, and
wherein the third wiring is between at least a part of the first wiring from the first end to the first node, and at least a part of the second wiring from the third end to the third node.

5. A power amplifier device having the power amplifier circuit according to claim 1, the device comprising:
a semiconductor chip that comprises the first carrier amplifier, the first peak amplifier, the second carrier amplifier, and the second peak amplifier; and
a board that comprises the first wiring, the second wiring, the third wiring, and the balun therein, and that further comprises the semiconductor chip.

6. The power amplifier device according to claim 5,
wherein the board further comprises a first conductive layer, and
wherein at least a part of the first wiring, at least a part of the second wiring, and at least a part of the third wiring are in the first conductive layer.

7. The power amplifier device according to claim 5,
wherein the board comprises a first conductive layer, a second conductive layer, and a third conductive layer between the first conductive layer and the second conductive layer, and
wherein the first wiring, the second wiring, and the third wiring are in the first conductive layer, the second conductive layer, and the third conductive layer, respectively.
